(19) United States
(12) Patent Application Publication
(10) Pub. No.: US 2016/0178780 A1
(43) Pub. Date: Jun. 23, 2016

(54) Antenna Transmitter Health Determination and Borehole Compensation for Electromagnetic Measurement Tool

(71) Applicant: Schlumberger Technology Corporation, Sugar Land, TX (US)

(72) Inventors: Joshua W. Gibson, Missouri City, TX (US); Libo Yang, Katy, TX (US); Gary A. Hazen, Houston, TX (US); Mark A. Fredette, Houston, TX (US); Fernando Garcia-Osuna, Sugar Land, TX (US)

(21) Appl. No.: 14/957,543

(22) Filed: Dec. 2, 2015

Related U.S. Application Data
(60) Provisional application No. 62/093,900, filed on Dec. 18, 2014.

(51) Int. Cl. G01V 3/10; G01R 31/28

(52) U.S. Cl. CPC G01V 3/10; G01R 31/2822

(57) ABSTRACT

Systems and methods for antenna transmitter health determinations and borehole compensation for an electromagnetic measurement tools are provided. The input current to an antenna transmitter of an electromagnetic measurement tool may be measured using a current measurement circuit. An output voltage proportional to the input current may be provided and compared to a threshold to determine the health of the antenna transmitter. A replacement borehole compensation matrix for calculating a combined attenuation measurement may be selected based on an identified unhealthy antenna transmitter.

### CROSS-REFERENCE TO RELATED APPLICATIONS

The present disclosure claims priority to U.S. Provisional Application Ser. No. 62/093,900 filed Dec. 18, 2014, the entirety of which is incorporated by reference.

### FIELD OF THE INVENTION

Aspects relate to wellbore drilling systems. More specifically, aspects relate to a tool for an antenna transmitter heath determination and borehole compensation for electromagnetic measurement.

### BACKGROUND

This disclosure relates to generally relates to electromagnetic measurement tools, and more particularly to, determining antenna transmitter health and borehole compensation in such tools.

Electromagnetic measurement tools may be used in downhole applications, such as logging-while-drilling (LWD) and wireline logging applications to monitor formation properties using electromagnetic measurements. For example, electromagnetic measurements may be used to determine a subterranean formation resistivity. An electromagnetic measurement tool may include an array of antennas, such as transmitters and receivers. Transmitters in a tool may create a primary magnetic field that generates eddy currents in a formation. The eddy currents may generate a secondary magnetic field sensed by the receivers in the tool. The ratio of receiver voltage to transmitter current is directly proportional to the resistivity of the formation. Relatively high temperature and/or high pressure environments, may affect antenna impedance, and consequently, antenna integrity due to antenna shorts and insulation failures. Such environments may, over time, degrade antennas.

### SUMMARY

Embodiments of this disclosure relate to various systems, methods, and devices for determining antenna transmitter health and borehole compensation in electromagnetic measurement tools. In some embodiments, a method is provided that includes receiving a voltage proportional to an input current provided to an antenna transmitter of an electromagnetic measurement tool disposed in a wellbore. The electromagnetic measurement tool includes the antenna transmitter and at least one antenna receiver. The method also includes comparing the voltage to a threshold voltage and identifying the antenna transmitter as unsuitable for operation if the voltage is below the threshold voltage.

In some embodiments, a method is provided that includes monitoring at least one antenna transmitter of an electromagnetic measurement tool disposed in a wellbore. The electromagnetic measuring measurement tool includes a plurality of antenna transmitters and at least one antenna receiver. The method further includes determining a combined attenuation measurement using a first borehole compensation matrix and identifying one of the plurality of antenna transmitters as unsuitable for operation. The method also includes selecting, based on the identified antenna transmitter, a replacement borehole compensation matrix from a plurality of borehole compensation matrices and determining a combined attenuation measurement using the replacement compensation matrix associated with the plurality of antenna transmitters.

In some embodiments, a system is provided having a processor and a memory storing computer-executable instructions. When executed, the computer-readable instructions cause the processor to monitor at least one antenna transmitter of an electromagnetic measurement tool disposed in a wellbore, the electromagnetic measurement tool comprising a plurality of antenna transmitters and at least one antenna receiver and determine a combined attenuation measurement using a first borehole compensation matrix associated with the plurality of antenna transmitters. The computer-readable instructions also cause the processor to identify one of the plurality of antenna transmitters as unsuitable for operation and select, based on the identified antenna transmitter, a replacement borehole compensation matrix from a plurality of borehole compensation matrices and select, based on the identified antenna transmitter, a replacement borehole compensation matrix from a plurality of borehole compensation matrices. The computer-readable instructions also cause the processor to determine a combined attenuation measurement using the replacement compensation matrix associated with the plurality of antenna transmitters.

In some embodiments, a method is provided that includes receiving a first signal from at least one receiver associated with an electromagnetic measurement tool; the received signal responsive to operation of an antenna transmitter of the electromagnetic measurement tool and comparing a property of the received signal to a threshold. The property includes one of a peak voltage, a linearity of the received signal, or an average phase of the first signal and a second signal received at the at least one receiver. The method also includes identifying the antenna transmitter as unsuitable for operation if the property is below the threshold voltage.

### BRIEF DESCRIPTION OF THE DRAWINGS

FIG. 1 is a schematic diagram of an example well site system in accordance with an embodiment of the disclosure;

FIG. 2 is a diagram of an example electromagnetic measurement tool in accordance with an embodiment of the disclosure;

FIG. 3 is an example circuit schematic depicting monitoring of an input current to an antenna transmitter of an electromagnetic measurement tool in accordance with an embodiment of the disclosure;

FIG. 4 is an example graphical plot of depicting an unhealthy antenna voltage and healthy antenna voltage versus time in accordance with an embodiment of the disclosure;

FIG. 5 is a block diagram of an example process for determining antenna transmitter health of an electromagnetic measurement tool by measuring input current to an antenna transmitter in accordance with an embodiment of the disclosure;

FIG. 6 is a block diagram of an example process for determining antenna transmitter health of an electromagnetic measurement tool by monitoring a receiver signal at multiple transmitter frequencies in accordance with an embodiment of the disclosure;

FIG. 7 is an example graphical plot of received receiver signals versus transmitter frequency in accordance with an embodiment of the disclosure;

FIG. 8 is a block diagram of an example process for determining antenna transmitter health of an electromagnetic measurement tool by determining a receiver signal linearity at over an antenna transmitter amplitude range in accordance with an embodiment of the disclosure;

FIG. 9 is a block diagram of an example process for determining antenna transmitter health of an electromagnetic measurement tool by determining an average phase of received signals in accordance with an embodiment of the disclosure;

FIG. 10 is a block diagram of an example process for using a replacement borehole compensation matrix in accordance with an embodiment of the disclosure; and

FIG. 11 is a block diagram of an example control system in accordance with an embodiment of the disclosure.

### DETAILED DESCRIPTION

Described herein are various embodiments for antenna transmitter health determinations and borehole compensation for electromagnetic measurement tools. In some embodiments, the input current to an antenna transmitter of an electromagnetic measurement tool may be measured using a current measurement circuit. An output voltage proportional to the input current may be provided by the current measurement circuit. In some embodiments, if the output voltage is greater than a threshold voltage, the electromagnetic measurement tool may be determined to be healthy (i.e., suitable for operation). If the output voltage is less than or equal to the threshold voltage, the electromagnetic measurement tool may be determined to be unhealthy (i.e., unsuitable for operation). In some embodiments, a notification of an unhealthy antenna transmitter may be provided in a control system coupled to the electromagnetic measurement tool.

In some embodiments, a receiver signal at a receiver associated with an electromagnetic measurement tool may be monitored over a frequency range of an antenna transmitter. The receiver signal may be compared to a typical receiver signal over the frequency range to determine whether the antenna transmitter is healthy (i.e., suitable for operation) or unhealthy (i.e., unsuitable for operation). In some embodiments, the linearity of a receiver signal at a receiver associated with an electromagnetic measurement tool may be monitored over an amplitude range of an antenna transmitter. The linearity of the receiver signal may be compared to a threshold linearity to determine whether the antenna transmitter is healthy (i.e., suitable for operation) or unhealthy (i.e., unsuitable for operation). In some embodiments, an average phase of two received signals from two receivers associated with electromagnetic measurement tool may be determined. The average phase may be compared to a threshold phase value to determine whether the antenna transmitter is healthy (i.e., suitable for operation) or unhealthy (i.e., unsuitable for operation).

In some embodiments, when a transmitter is determined to be unhealthy (e.g., a transmitter fails or degrades) a replacement borehole compensation matrix may be selected to combine the attenuation measurements from the remaining transmitters. In such embodiments, an antenna transmitter of an electromagnetic measurement tool may be monitored while the tool is downhole in a well. If the antenna transmitter is determined to be unhealthy (i.e., unsuitable for operation), the unhealthy antenna transmitter may be identified and a replacement borehole compensation matrix may be selected from a plurality of borehole compensation matrices based on the identified antenna transmitter. For example, in an embodiment having a five antenna transmitter electromagnetic measurement tool, five replacement borehole compensation matrices each corresponding to one of the five antenna transmitters may be selected. After selection of a replacement borehole compensation matrix, the electromagnetic measurement tool may continue to be operated using the selected borehole compensation matrix.

These and other embodiments of the disclosure will be described in more detail through reference to the accompanying drawings in the detailed description of the disclosure that follows. This brief introduction, including section titles and corresponding summaries, is provided for the reader's convenience and is not intended to limit the scope of the claims or the proceeding sections. Furthermore, the techniques described above and below may be implemented in a number of ways and in a number of contexts. Several example implementations and contexts are provided with reference to the following figures, as described below in more detail. However, the following implementations and contexts are but a few of many.

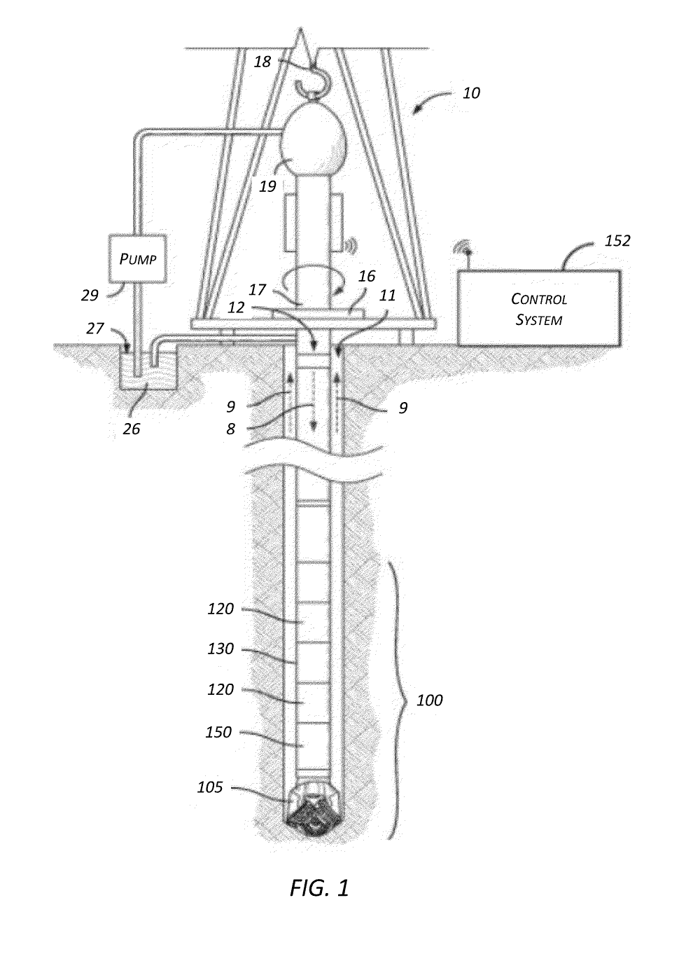

FIG. 1 is a diagram that illustrates an example well site system 10 in accordance with one or more embodiments of the disclosure. Such a well site system 10 can be deployed in either onshore or offshore applications. In this type of system, a borehole (also referred to as a “wellbore”) 11 may be formed in subsurface formations by rotary drilling. Some embodiments can also use directional drilling.

A drill string 12 may be suspended within the borehole 11 and may have a bottom hole assembly (BHA) 100 which includes a drill bit 105 at its lower end. The surface system may include a platform and derrick assembly positioned over the borehole 11, with the assembly including a rotary table 16, kelly 17, hook 18 and rotary swivel 19. In a drilling operation, the drill string 12 may be rotated by the rotary table 16, which may engage the kelly 17 at the upper end of the drill string. The drill string 12 may be suspended from a hook 18, attached to a traveling block, through the kelly 17 and a rotary swivel 19 which may permit rotation of the drill string 12 relative to the hook 18. In other embodiments, a top drive system may be used.

Drilling fluid or mud 26 may be stored in a pit 27 formed at the well site. A pump 29 may deliver the drilling fluid 26 to the interior of the drill string 12 via a port in the swivel 19, which may cause the drilling fluid 26 to flow downwardly through the drill string 12, as indicated by the directional arrow 8 in FIG. 1. The drilling fluid may exit the drill string 12 via ports in the drill bit 105, and may then circulate upwardly through the annulus region between the outside of the drill string 12 and the wall of the borehole, as indicated by the directional arrows 9. In this manner, the drilling fluid may lubricate the drill bit 105 and carry formation cuttings up to the surface as it is returned to the pit 27 for recirculation.

The drill string 12 may include a BHA 100. In the illustrated embodiment, the BHA 100 may be shown as having one MWD module 130 and multiple LWD modules 120 depicting a second LWD module 120). As used herein, the term “module” as applied to MWD and LWD devices is understood to mean either a single tool or a suite of multiple tools contained in a single modular device. Additionally, the BHA 100 may include a rotary steerable system (RSS), a motor 150 and the drill bit 105.

The LWD modules 120 may be housed in a drill collar and may include one or more types of logging tools. The LWD modules 120 may further include capabilities for measuring, processing, and storing information, as well as for communicating with the surface equipment. By way of example, the LWD module 120 may include an electromagnetic measurement tool. In accordance with various embodiments, the electromagnetic measurement tool may include any number of transmitter and receiver antennas for acquisition of electromagnetic measurements.

The MWD module 130 may also be housed in a drill collar, and can contain one or more devices for measuring characteristics of the drill string 12 and drill bit 150. The MWD module 130 can include one or more of a weight-on-bit measuring device, a torque measuring device, a vibration measuring device, a shock measuring device, a stick/slip measuring device, a direction measuring device, and/or an inclination measuring device (the latter two sometimes being referred to collectively as a D&I package). The MWD tool 130 may further include an apparatus for generating electrical power for the downhole system. For instance, power generated by the MWD tool 130 may be used to power the MWD tool 130 and the LWD tool(s) 120. In some embodiments, this apparatus may include a mud turbine generator powered by the flow of the drilling fluid 26. It is understood, however, that other power and/or battery systems may be employed.

The operation of the assembly 10 of FIG. 1 may be controlled using control system 152 located at the surface. The control system 152 may include one or more processor-based computing systems. In the present context, a processor may include a microprocessor, programmable logic devices (PLDs), field-gate programmable arrays (FPGAs), application-specific integrated circuits (ASICs), system-on-a-chip processors (SoCs), or any other suitable integrated circuit capable of executing encoded instructions stored, for example, on tangible computer-readable media (e.g., read-only memory, random access memory, a hard drive, optical disk, flash memory, etc.). Such instructions may correspond to, for instance, workflows and the like for carrying out a drilling operation, algorithms and routines for processing data received at the surface from the BHA 100 (e.g., as part of an inversion to obtain one or more desired formation parameters), and so forth.

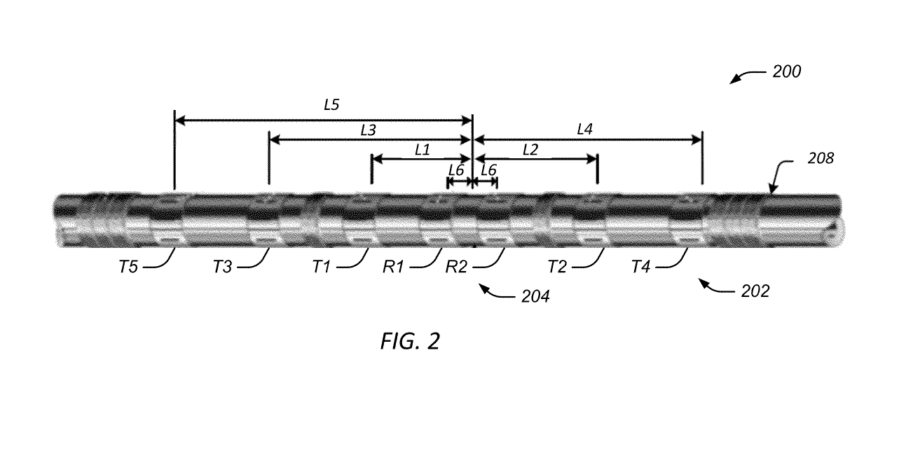

FIG. 2 is a diagram that illustrates an example electromagnetic measurement logging tool (also referred to as a “tool”) 200 in accordance with one or more embodiments of the disclosure. The tool 200 may be part of one of the LWD modules 120 of FIG. 1. The tool 200 may be a multi-spacing non-directional electromagnetic propagation or induction tool. In one embodiment, the tool 200 may be capable of facilitating measurements at multiple frequencies. For example, in some embodiments the tool 200 may facilitate measurements at approximately 400 kHz and approximately 2 MHz. In other embodiments, other suitable frequencies may be used. The measurement tool 200 may include an array of antennas, including multiple transmitter antenna systems (T) 202 (e.g., first, second, third, fourth and fifth transmitter antennas systems T1, T2, T3, T4, T5, respectively) and multiple receiver antenna systems (R) 204 (e.g., first and receiver antenna systems R1 and R2, respectively), spaced axially along a tool body 206. The multiple transmitter antenna systems T1, T2, T3, T4, and T5 may be spaced at distances of L1, L2, L3, L4, and L5, respectively, from a measurement point. Additionally, the multiple receiver antenna systems R1 and R2 may each be spaced at a similar distance of L6 away from the measurement point. In one example embodiment, the tool 200 may be capable of generating approximately 20 measurement channels, including two measurements (e.g., attenuation and phase shift measurements) for five spacings (e.g., each of L1-L5 of the five transmitters T1-T5) at two frequencies (e.g., at approximately 400 kHz, and approximately 2 MHz).

In certain implementations, some or all of the transmitter antenna systems 202 (e.g., transmitter antennas systems T1-T5) and receiver antenna systems 204 (e.g., receiver antenna systems R1 and R2) of the tool 200 may include axial antennas. As used herein, an axial antenna may be an antenna associated with a dipole moment approximately parallel with the longitudinal axis of the tool 200. An axial antenna may include an antenna coil wound about the circumference of the logging tool 200 such that the plane of the antenna is approximately orthogonal to the tool axis. In some embodiments, the antenna coil is embedded in composite material located between an outer shield and a collar recess of the tool 200. An axial antenna may produce a radiation pattern equivalent to a dipole along the axis of the tool 200 (by convention the z-direction). As discussed above, electromagnetic measurements determined by axially oriented antennas may be referred to as “conventional” or “non-directional measurements.”

In some embodiments, the tool 200 may lack tilted or transverse antennas, and thus, may not be designed to provide directional measurements. Accordingly, with respect to electromagnetic resistivity measurements, the tool 200 may be configured to provide non-directional resistivity responses. In some embodiments, the tool 200 may include one or more directional antennas. For instance, the tool 200 may include tilted receiver antennas and a transverse transmitter antenna, as well as several axial transmitter and receiver antennas and, thus, may be capable of acquiring both directional and non-directional resistivity measurements.

The logging tool 200 may be a model of a tool from Schlumberger Technology Corporation of Sugar Land, Tex. Examples of tools available from Schlumberger that are capable of making non-directional electromagnetic measurements may include those referred to by the names ARCVISION, CDR and ECOSCOPE. An example of a tool available from Schlumberger that is capable of acquiring both directional and non-directional resistivity measurements may include a tool referred to by the name of PERISCOPE (which may include tilted receiver antennas and a transverse transmitter antenna, as well as several axial transmitter and receiver antennas). It will be understood, however, that the embodiments disclosed herein are not limited to any particular electromagnetic measurement tool configuration, and that the tool 200 depicted in FIG. 2 is merely one example of a suitable electromagnetic measurement tool. Moreover, while the tool 200 is described with reference to FIGS. 1 and 2 as being used in an LWD context, it will be understood that the tool 200 may also be conveyed by other suitable means, such as wireline, slickline, coil tubing, wired drill pipe, and so forth.

The impedance of the transmitter antennas described may change in response to relatively high temperature conditions. For example, in some instances, the impedance of an antenna transmitter may increase by up to a factor of approximately three over a period of time, resulting in a drop in current and signal gain. The increasing impedance of an antenna transmitter may result in a signal-to-noise ratio that becomes unacceptably low, especially in certain formations (e.g., conductive formations). Moreover, an increased impedance value of a transmitter antenna may increase the chance of antenna shorts and insulation failures due to the degradation of antenna construction materials over time at the relatively high temperature conditions.

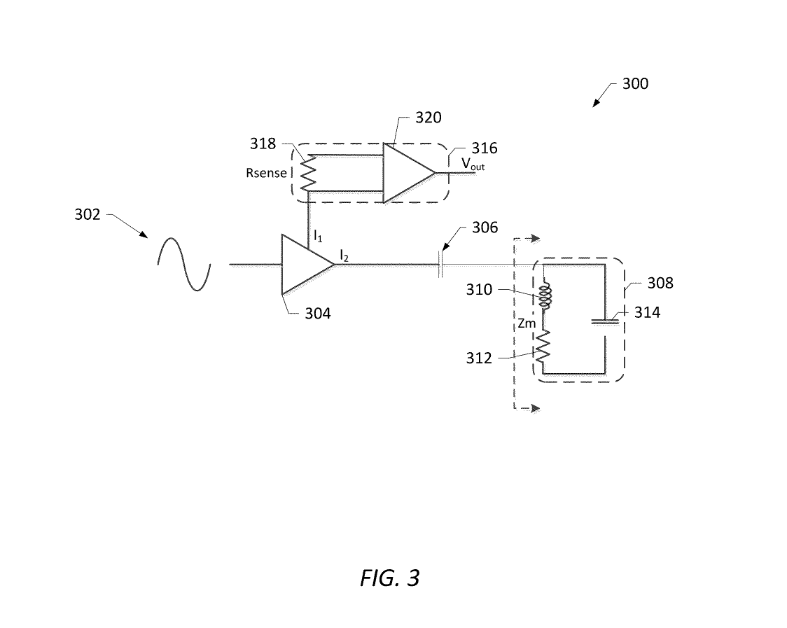

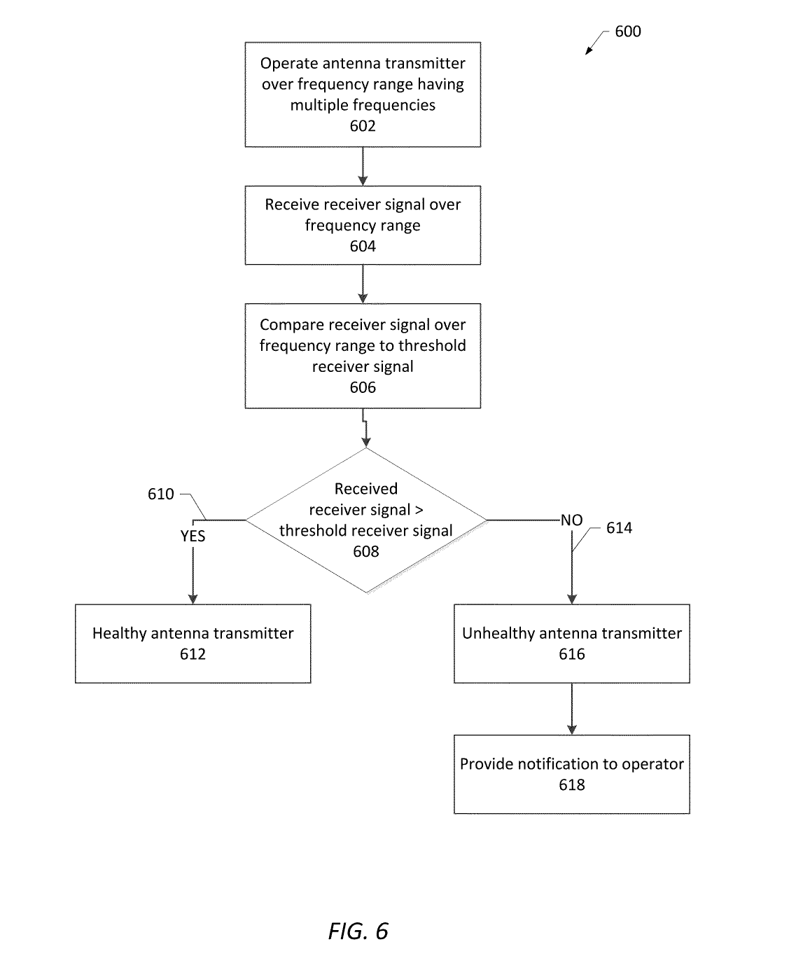

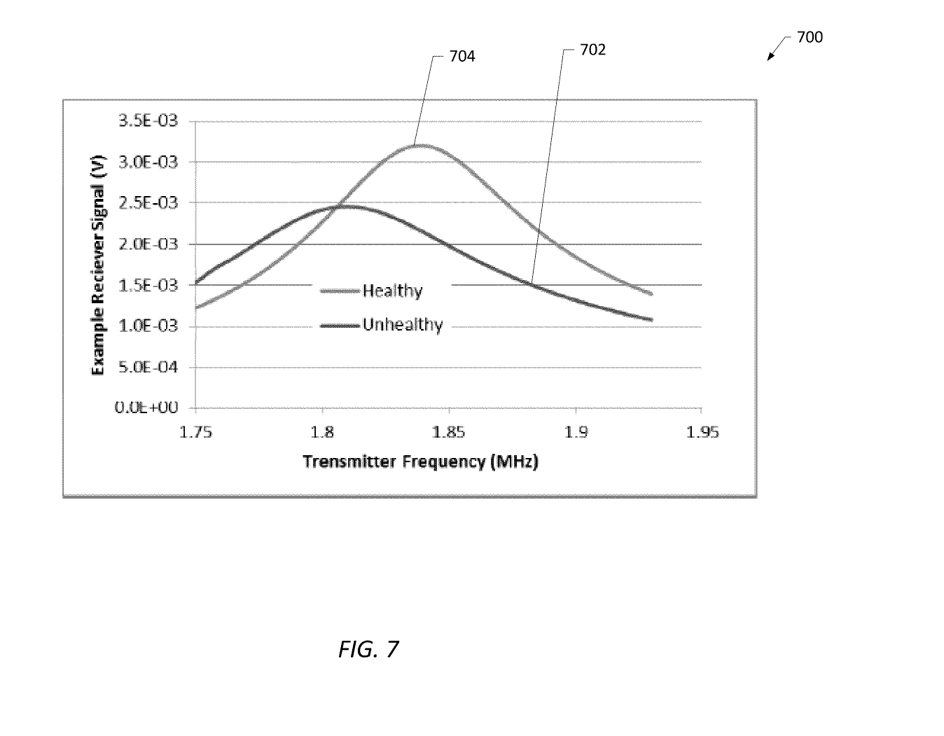

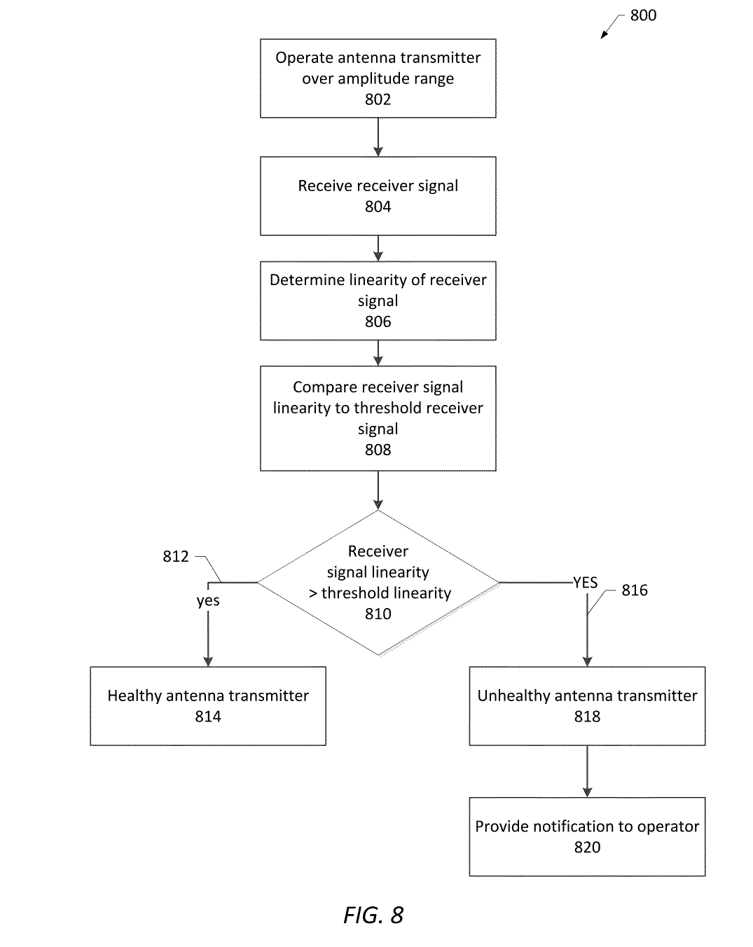

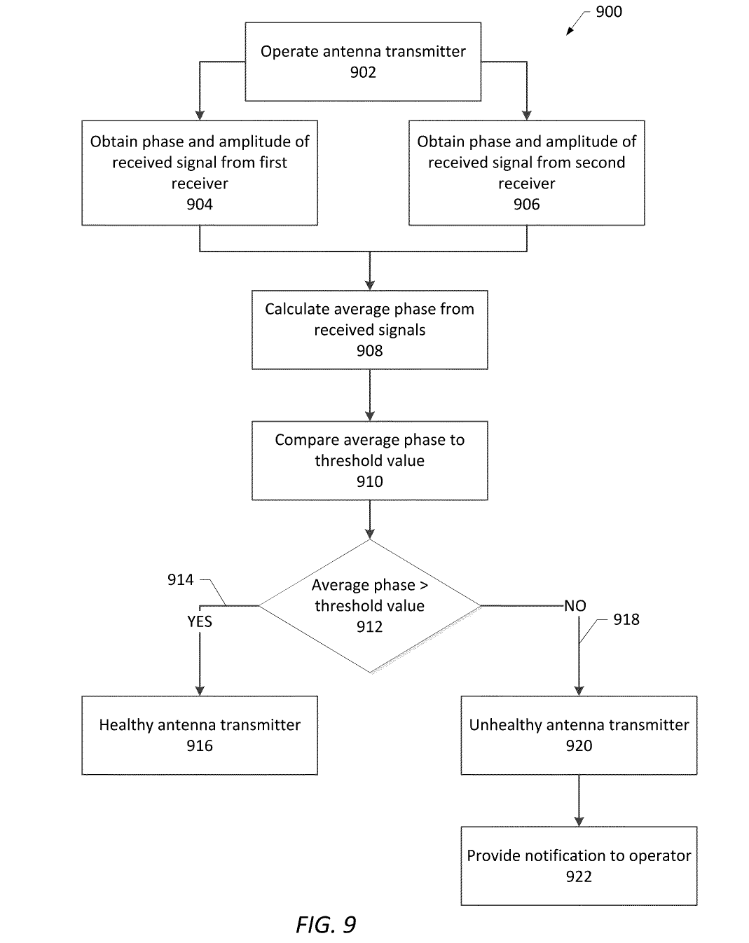

With the foregoing in mind, FIGS. 3-9 depict various embodiments for determining the health of an antenna transmitter. In some embodiments, as depicted in FIGS. 3-5 and as described below, the input current to an antenna transmitter may be measuring via a sense resistor and output voltage. In some embodiments, as depicted in FIGS. 6 and 7, a signal from a receiver may be measured at different antenna transmitter frequencies. In some embodiments, as depicted in FIG. 8, the linearity of a signal from a receiver may be determined at different antenna transmitter amplitudes. In some embodiments, as depicted in FIG. 9, the average phase of two signals from two antenna receivers may be determined.

FIG. 3 depicts an example circuit schematic 300 illustrating the monitoring of an input current I₁ to an antenna transmitter in accordance with an embodiment of the disclosure. The circuit schematic 300 depicts an RF input voltage 302 provided to a high power drive block 304 that is coupled to a turning circuit (represented by capacitor 306). FIG. 3 also depicts a transmitter antenna transmitter 308 (represented by the depicted antenna model) having an inductance Zₘ and including a inductor 310 (e.g., a solenoid), resistor 312, and capacitor 314. As shown in FIG. 3, the input current I₁ may be received by the high power driver block 304 which then outputs an output current I₂ to the antenna transmitter 308.

The RF input voltage 302 may be provided to the high power drive block 304 which outputs the output current I₂. In some embodiments, the high power drive block 304 may include several current-driven elements having input and output signals. The output current I₂ may generate the primary magnetic field of the antenna transmitter 308 as it passes through the inductor 310. The turning circuit 306 may resonate the antenna transmitter 308 for the voltage-driven system depicted in FIG. 3. The antenna transmitter 308 may be primarily inductive to lower the overall impedance Zm to a small real (i.e., resistive) value. Thus, the smaller the real impedance value, the more current I₂ will flow for a given RF input voltage 302.

FIG. 3 also depicts a current measurement circuit 316 coupled to the high power driver block 304. The current measurement circuit 316 may include a sense resistor 318 (Rsense) coupled to a driver block 320. The drive block 320 may output a monitored voltage Vₒᵤₜ that is proportional to the impedance Zₘ of the antenna model 308. In some embodiments, the monitored voltage Vₒᵤₜ may be provided to a component (e.g., logic controller) of a control system (e.g., control system 152). In some embodiments, the current measurement circuit 316 may be added to an existing electromagnetic measurement tool or implemented during manufacture of an electromagnetic measurement tool. In other embodiments, changes in impedance of the antenna transmitter 308 may be measured using an inductor coupled between the high power drive block 304 and the antenna transmitter 308. In such embodiments, a resistor may be coupled to the inductor and may be used to produce a voltage. The voltage may be monitored and used in a manner similar to the monitored voltage Vₒᵤₜ described herein.

The sense resistor 318 may establish a voltage proportional to the impedance Zₘ, and the voltage may be provided to the drive block 320 and a representative signal output as the monitored voltage Vₒᵤₜ. In some embodiments, the monitored voltage Vₒᵤₜ may be provided to a control system (e.g., control system 152). The monitored voltage Vₒᵤₜ may be compared to a threshold voltage to monitor the health of the antenna transmitter 308. If the monitored voltage Vₒᵤₜ falls below the threshold voltage, the impedance Zₘ of the antenna transmitter 308 may be determined to be below an acceptable value and the antenna transmitter 308 may be determined to be unhealthy. If the monitored voltage Vₒᵤₜ is greater or equal to the threshold voltage, the antenna transmitter 308 may be determined to have maintained an impedance Zₘ within a suitable operating range and the antenna transmitter 308 may be determined to be healthy. For example, in some embodiments, the monitored voltage Vₒᵤₜ and a threshold voltage may be provided to a comparator that provides an output (e.g., a binary digital output) based on the comparison between the monitored voltage Vₒᵤₜ and the threshold voltage.

In some embodiments, the monitored voltage Vₒᵤₜ may be measured while the antenna transmitter 308 (and tool having the antenna transmitter 308) is downhole. For example, during use of an electromagnetic measurement tool (e.g., the tool) such as in the drilling system 10 described above, the monitored voltage Vₒᵤₜ may be used to periodically or continuously monitor the health of an antenna transmitter of the electromagnetic measurement tool, such as via the control system 152 that may receive the monitored voltage Vₒᵤₜ. Thus, in such embodiments, the health of an antenna transmitter of the electromagnetic measurement tool without removing the tool from downhole or interrupting a LWD operation or other operation. In some embodiments, a notification (e.g., a flag or other notification) may be provided in a control system (e.g., control system 152) to notify an operator that the antenna transmitter is unhealthy (i.e., that the impedance has changed to an unacceptable value). In some embodiments, the health status of the antenna transmitter 308 may be periodically or continuously provided in a control system (e.g., control system 152).

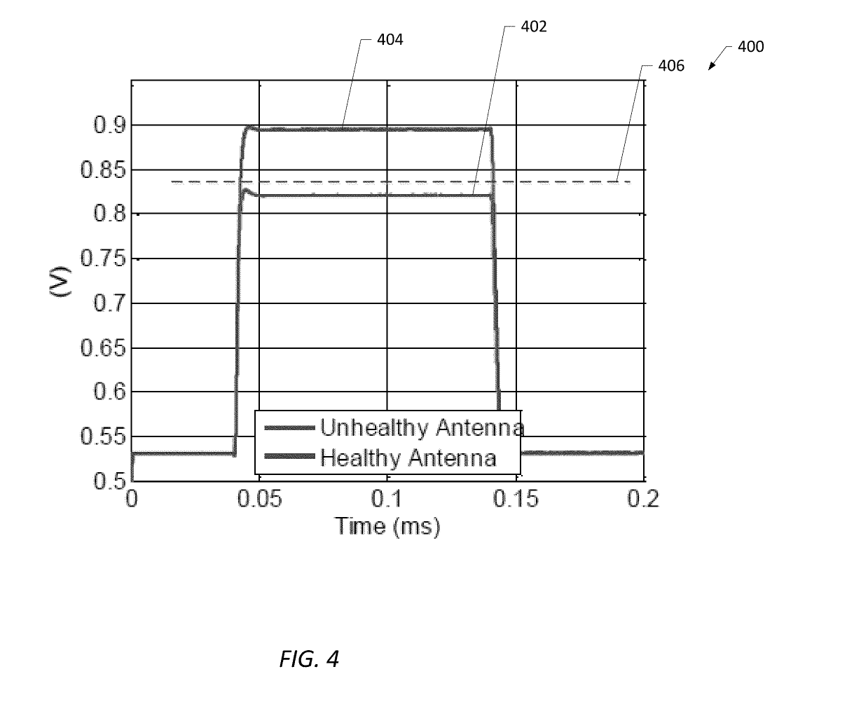

FIG. 4 depicts an example graphical plot 400 that shows an unhealthy antenna voltage and healthy antenna voltage in accordance with an embodiment of the disclosure. The plot 400 depicts a voltage (in volts) on the y-axis and time (in milliseconds) on the x-axis. The monitored voltage Vₒᵤₜ received from the current measurement circuit 316 may be plotted versus time for an unhealthy antenna (line 402) and a healthy antenna (line 404). As will be appreciated, because the antenna transmitter does not fire continuously, each line 402 and 404 may be a square pulse. As shown in FIG. 4, for example, the healthy antenna voltage line 404 may be greater than the unhealthy antenna voltage line 402. Thus, a threshold voltage 406 may be determined between the healthy antenna voltage line 404 and the unhealthy antenna voltage line 402.

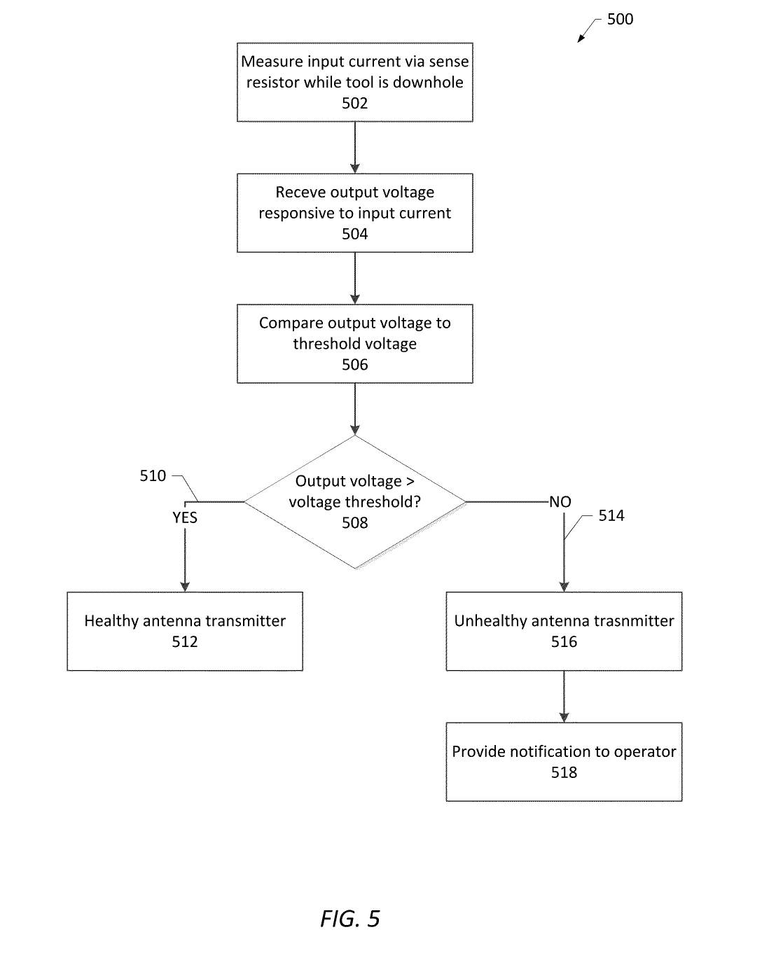

FIG. 5 depicts an example process 500 for determining antenna transmitter health of an electromagnetic measurement tool by measuring input current in accordance with an embodiment of the disclosure. Initially, the input current may be measured while the electromagnetic measurement tool is downhole (block 502), such as by using the current measurement circuit 316 described above. An output voltage responsive to the input current and indicative of the impedance of the antenna transmitter, e.g., the monitored output voltage Vₒᵤₜ described above, may be received (block 504). In some embodiments, the output voltage may be compared to a voltage threshold (block 506) to determine whether the output voltage is above the voltage a threshold (decision block 508). For example, in some embodiments, the average output voltage over a time period (e.g., a time period that coincided with operation of the electromagnetic measurement tool while downhole) may be compared to a voltage threshold.

If the output voltage is greater than the voltage threshold (line 510), the antenna transmitter may be determined to be healthy (i.e., suitable for operation) (block 512). In such instances, the received output voltage above the threshold voltage may indicate that the impedance of the antenna transmitter is acceptable for operation of the electromagnetic measurement tool. If the output voltage is less than or equal to the voltage threshold (line 512), the antenna transmitter may be determined to be unhealthy (i.e., unsuitable for operation) (block 514). In such instances, the received output voltage below the voltage threshold may indicate that the antenna transmitter impedance is unsuitable for operation of the electromagnetic measurement tool. In some embodiments, if an antenna transmitter is determined to be unhealthy, a notification (e.g., a visual notification, an audio notification, or both) may be provided to an operator (block 516). For example, a notification may be displayed in a display of a control system (e.g., control system 152) used to operate the electromagnetic measurement tool having the unhealthy transmitter.

In some embodiments, the process 500 described above may be performed for each antenna transmitter of an electromagnetic measurement tool. For example, for the electromagnetic measurement tool 200 described above, the process 500 may be performed for each antenna transmitter T1, T2, T3, T4, and T5 to determine the health of each transmitter. In such embodiments, each antenna transmitter may include a current measurement circuit, e.g., the current measurement circuit 316 described above. In such embodiments, the monitoring of each transmitter T1, T2, T3, T4, and T5 may be performed in parallel as each antenna transmitter is transmitting while the electromagnetic measurement tool is downhole.

In some embodiments, the health of an antenna transmitter may be determined by monitoring a receiver signal at multiple transmitter frequencies. FIG. 6 depicts an example process 600 for determining the health of an antenna transmitter of an electromagnetic measurement tool by monitoring a receiver signal at multiple transmitter frequencies in accordance with an embodiment of the disclosure. Initially, an antenna transmitter of an electromagnetic measurement tool may be operated over a frequency range having multiple frequencies (block 602). For example, an antenna transmitter may transmit at each frequency in the frequency range, and the transmission may be received by a receiver. Next, the receiver signal produced over the frequency range may be detected (block 604). In some embodiments, the receiver signal may be received from a receiver of the electromagnetic measurement tool having the antenna transmitter, e.g., the receiver R1 and R2 of tool 200. In some embodiments, the receiver may be a loop wrapped around the antenna transmitter, e.g., a loop of wire wrapped around one of the antenna transmitters T1, T2, T3, T4, and T5 of the tool 200. In some embodiments, the receiver may be any suitable magnetic sensor positioned to detect transmissions from the antenna transmitter being evaluated.

As shown in FIG. 6, the received receiver signal over the frequency range may be compared to a threshold receiver signal (e.g., a typical receiver signal over the frequency range) (block 606) to determine whether the received receiver signal is below the threshold receiver signal (block 608). Embodiments of the disclosure may use any suitable comparison technique to compare the received receiver signal to a threshold receiver signal. For example, in some embodiments the peak frequency response changes may be compared. In some embodiments, the Q factor (or bandwidth Δf/f) may be compared. In some embodiments, the amplitude of the receiver signal may be compared.

If the received receiver signal is above the threshold receiver signal (line 610), the antenna may be determined to be healthy (i.e., suitable for operation) (block 612). If the detected receiver signal is below the threshold receiver signal (line 614), the antenna may be determined to be unhealthy (i.e., unsuitable for operation) (block 616). For example, a change in peak frequency response may be indicative of capacitive changes in an older antenna transmitter. In another example, changes in the Q factor or bandwidth may be indicative of a power loss increase (i.e., a resistive increase) in the antenna transmitter. Similarly, in another example, an amplitude decrease may also be indicative of a power loss increase (i.e., a resistive increase) in the antenna transmitter. In some embodiments, if an antenna transmitter is determined to be unhealthy, a notification (e.g., a visual notification, an audio notification, or both) may be provided to an operator (block 618). For example, a notification may be displayed in a display of a control system (e.g., control system 152) used to operate the electromagnetic measurement tool having the unhealthy transmitter.

In some embodiments, the process 600 described above may be performed for each antenna transmitter of an electromagnetic measurement tool. For example, for the electromagnetic measurement tool 200 described above, the process 600 may be performed for each antenna transmitter T1, T2, T3, T4, and T5 to determine the health of each transmitter. For example, in such embodiments, the antenna transmitters of an electromagnetic measurement tool may be evaluated while the tool is at the surface and before the tool is inserted downhole. As noted above, in some embodiments the receivers of the tool may be used to provide the received receiver signal responsive to the antenna transmitter or, in other embodiments, a wire loop or other suitable magnetic sensor may be positioned to detect the transmission from the antenna transmitter being evaluated.

FIG. 7 depicts an example graphical plot 700 of received receiver signals (line 702 and line 704) versus transmitter frequency in accordance with an embodiment of the disclosure. The plot 700 depicts a voltage (in volts) of a receiver signal on the y-axis and a transmitter frequency (in MHz) on the x-axis. The received receiver signal detected from an unhealthy antenna transmitter (line 702) and a healthy transmitter (line 704) may be plotted versus transmitter frequency. As shown in FIG. 7 various parameters of the receiver signals 702 and 704, such as peak voltage, may differ and be used in a comparison of the unhealthy receiver signal (line 702) to a threshold receiver signal.

In some embodiments, the health of an antenna transmitter may be evaluated by determining the linearity of a received receiver signal. FIG. 8 depicts an example process 800 for determining antenna transmitter health of an electromagnetic measurement tool by determining a receiver signal linearity at over an antenna transmitter amplitude range in accordance with an embodiment of the disclosure. Initially, an antenna transmitter of an electromagnetic measurement tool may be operated over an amplitude range having multiple amplitudes (block 802). The receiver signal over the amplitude range may be received (block 804). The linearity of the received receiver signal may then be determined (block 806). In some embodiments, a linear regression may be performed to determine the linearity of the receiver signal. The linearity of the received receiver signal may be compared to a threshold linearity (block 808) to determine whether the detected receiver signal is below the threshold linearity (block 810). For example, in some embodiments, a numeric value of the linearity may be compared to the threshold linearity.

If the detected receiver signal linearity is above the threshold (line 810), the antenna may be determined to be healthy (i.e., suitable for operation) (block 812). If the detected receiver signal linearity is below the threshold linearity (line 814), the antenna may be determined to be unhealthy (i.e., unsuitable for operation) (block 816). In some embodiments, a notification may be provided to an operator (block 818). In some embodiment, in addition to the linearity of the receiver signal, the input current (e.g., the current I₁ described above) may also be monitored to check drive current vs. drive level. For example, the input current may be measured using the current measurement circuit 316 described above. In some embodiments, if an antenna transmitter is determined to be unhealthy, a notification (e.g., a visual notification, an audio notification, or both) may be provided to an operator (block 820). For example, a notification may be displayed in a display of a control system (e.g., control system 152) used to operate the electromagnetic measurement tool having the unhealthy transmitter.

In some embodiments, the process 800 described above may be performed for each antenna transmitter of an electromagnetic measurement tool. For example, for the electromagnetic measurement tool 200 described above, the process 800 may be performed for each antenna transmitter T1, T2, T3, T4, and T5 to determine the health of each transmitter. For example, in such embodiments, the antenna transmitters of an electromagnetic measurement tool may be evaluated while the tool is at the surface and before the tool is inserted downhole. As noted above, in some embodiments the receivers of the tool may be used to provide the received receiver signal responsive to the antenna transmitter or, in other embodiments, a wire loop or other suitable magnetic sensor may be positioned to detect the transmission from the antenna transmitter being evaluated.

In some embodiments, the average phase of signals at two receivers may be used to monitor antenna transmitter health of an electromagnetic measurement tool. FIG. 9 depicts an example process 900 for determining antenna transmitter health of an electromagnetic measurement tool by determining an average phase of received signals in accordance with an embodiment of the disclosure. Initially, an antenna transmitter of an electromagnetic measurement tool may be operated (block 902). The phase (φ₁) and amplitude of a received signal at a first receiver may be determined (block 904). Similarly, the phase (φ₂) and amplitude of a received signal at a second receiver may be determined (block 906). In some embodiments, the receiver signal may be received from an antenna receiver of the electromagnetic measurement tool having the antenna transmitter, e.g., the receiver R1 and R2 of tool 200. In some embodiments, the receiver may be a loop wrapped around the antenna transmitter, e.g., a loop of wire wrapped around one of the antenna transmitters T1, T2, T3, T4, and T5 of the tool 200. In some embodiments, the receiver may be any suitable magnetic sensor positioned to detect transmissions from the antenna transmitter being evaluated.

Next, the average of the two phases from the receiver signals may be calculated to determine an average phase (block 908), e.g., by calculating (φ₁₊φ₂/2. The average phase may be compared to a threshold value (block 910) to determine whether the average phase is above or below the threshold value (block 912). If the average phase is above the threshold value (line 914), the antenna transmitter may be determined to be healthy (i.e., suitable for operation) (block 916). If the average phase is below the threshold value (line 918), the antenna transmitter may be determined to be unhealthy (i.e., unsuitable for operation) (block 920). In some embodiments, a notification (e.g., a visual notification, an audio notification, or both) may be provided to an operator (block 922) if the antenna transmitter is unhealthy. For example, a notification may be displayed in a display of a control system (e.g., control system 152) used to operate the electromagnetic measurement tool having the unhealthy transmitter.

In some embodiments, the process 900 described above may be performed for each antenna transmitter of an electromagnetic measurement tool. For example, for the electromagnetic measurement tool 200 described above, the process 900 may be performed for each antenna transmitter T1, T2, T3, T4, and T5 to determine the health of each transmitter. For example, in such embodiments, the antenna transmitters of an electromagnetic measurement tool may be evaluated while the tool is at the surface and before the tool is inserted downhole.

As noted above, in some embodiments, an electromagnetic measurement tool may include an array of antennas, e.g., antenna array of the electromagnetic measurement tool 200. In such embodiments, each focus (e.g., F10, F16, F22, F28, and F34) may include a combination of attenuation measurements from at least three transmitters and two receivers. In such embodiments, gain errors during LWD operations may be removed by taking the ratio of receiver signals for a given transmitter to remove transmitter gain errors and then combining the transmitter signals so as to remove the receiver gain errors. In one example, a combination of attenuation measurements may be performed using a borehole compensation matrix in which each row of the borehole compensation matrix corresponds to a focus and each column of the borehole compensation matrix corresponds to a transmitter. For example, for an embodiment of an electromagnetic measurement tool having five transmitters, an example borehole compensation matrix may be the following:

$$[ \begin{matrix}+ 0.75 & + 0.50 & - 0.25 & 0.00 & 0.00 \\ + 0.25 & + 0.50 & + 0.25 & 0.00 & 0.00 \\ 0.00 & + 0.25 & + 0.50 & + 0.25 & 0.00 \\ 0.00 & 0.00 & + 0.25 & + 0.50 & + 0.25 \\ 0.00 & 0.00 & - 0.25 & + 0.50 & + 0.75\end{matrix} ]$$

In the borehole compensation matrix shown above, each row of the matrix corresponds to a focus, (e.g., F10, F16, F22, F28, and F34 from top to bottom). Each column of the borehole compensation matrix corresponds to an antenna transmitter (e.g., T1, T2, T3, T4, and T5 from left to right).

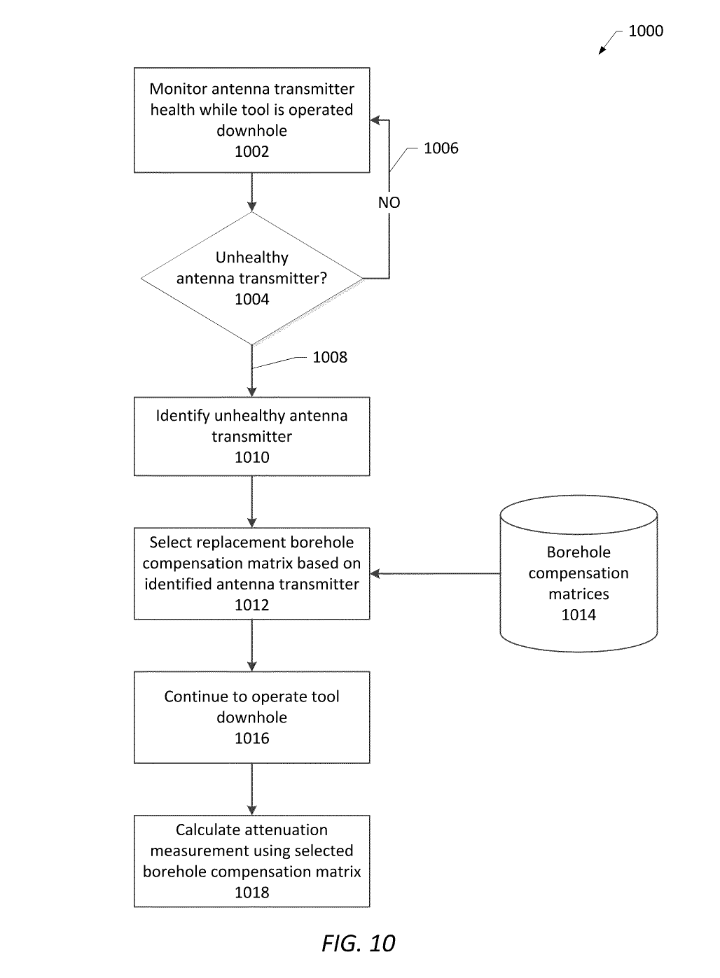

In some embodiments, when a transmitter is determined to be unhealthy (e.g., a transmitter fails or degrades) a replacement borehole compensation matrix may be selected to combine the attenuation measurements from the remaining transmitters. FIG. 10 depicts an example process 1000 for using a replacement borehole compensation matrix in accordance with an embodiment of the disclosure. Initially, the antenna transmitter health of an electromagnetic measurement tool may be monitored in real-time while the tool is operated downhole (block 1002). The monitoring may evaluate the transmitter health to determine whether am antenna transmitter is unhealthy (block 1004). In some embodiments, the process 1000 may use any one of the embodiments described above and illustrated in FIGS. 3-9 to determine the health of antenna transmitters. For example, in some embodiments, the process 1000 may determine the health of antenna transmitters by measuring the input current to a high output driver block as illustrated in FIGS. 3-5 and described above. In such embodiments, the process 1000 may continuously monitor the antenna transmitter health in real-time while the electromagnetic measurement tool is downhole. In such embodiments, the process 1000 may enable continued downhole operation of an electromagnetic measurement tool having an unhealthy antenna transmitter without removing the tool from downhole.

If all antenna transmitters are healthy (line 1006), the antenna health may continue to be monitored (block 1002). If an antenna transmitter is unhealthy (line 1008), the unhealthy transmitter may be identified (1010). For example, for an electromagnetic measurement tool having five antenna transmitters T1, T2, T3, T4, and T5, one of the antenna transmitters may be identified as unhealthy.

Next, a replacement borehole compensation matrix may be selected (1012) from a stored collection (block 1014) of borehole compensation matrices based on the identified antenna transmitter. For example, multiple borehole compensation matrices may be stored in a memory of a control system (e.g., control system 152). As described below, for an embodiment having a five antenna transmitter electromagnetic measurement tool, five replacement borehole compensation matrices each corresponding to one of the five antenna transmitters may be stored. For example, in such embodiments, if antenna transmitter T1 is identified as the failed antenna transmitter, the replacement borehole compensation matrix corresponding to antenna transmitter T1 may be selected.

Examples of various replacement borehole compensation matrices are described below. Each example replacement borehole compensation matrix corresponds to a specific unhealthy transmitter of five transmitter-two receiver embodiment of an electromagnetic measurement tool, such as the tool 200 described above. For example, the borehole compensation matrix labeled BHC_{T1} corresponds to a matrix that may be used when the T1 transmitter fails, the borehole compensation matrix labeled BHC_{T2} corresponds to a matrix that may be used when the T2 transmitter fails, the borehole compensation matrix labeled BHC_{T3} corresponds to a matrix that may be used when the T3 transmitter fails, the borehole compensation matrix labeled BHC_{T4} corresponds to a matrix that may be used when the T4 transmitter fails, and the borehole compensation matrix labeled BHC_{T5} corresponds to a matrix that may be used when the T5 transmitter fails. In the borehole compensation matrices shown below, each row of the matrix corresponds to a focus, (e.g., F10, F16, F22, F28, and F34 from top to bottom). Each column of the borehole compensation matrices corresponds to an antenna transmitter (e.g., T1, T2, T3, T4, and T5 from left to right).

$${BHC}_{T 1} = [ \begin{matrix}0.00 & + 0.90 & 1.00 & - 0.40 & - 0.50 \\ 0.00 & + 0.60 & + 0.75 & - 0.10 & - 0.25 \\ 0.00 & + 0.30 & + 0.50 & + 0.20 & 0.00 \\ 0.00 & 0.00 & + 0.25 & + 0.50 & + 0.25 \\ 0.00 & 0.00 & - 0.25 & + 0.50 & + 0.75\end{matrix} ]$$

$${BHC}_{T 2} = [ \begin{matrix}+ 0.88 & 0.00 & - 0.25 & + 0.50 & - 0.13 \\ + 0.50 & 0.00 & + 0.25 & + 0.50 & - 0.25 \\ + 0.13 & 0.00 & + 0.50 & + 0.50 & - 0.13 \\ 0.00 & 0.00 & + 0.25 & + 0.50 & + 0.25 \\ 0.00 & 0.00 & - 0.25 & + 0.50 & + 0.75\end{matrix} ]$$

$${BHC}_{T 3} = [ \begin{matrix}+ 0.63 & + 0.60 & 0.00 & - 0.10 & - 0.13 \\ + 0.38 & + 0.60 & 0.00 & - 0.10 & + 0.13 \\ + 0.25 & + 0.50 & 0.00 & + 0.20 & + 0.25 \\ + 0.13 & 0.00 & 0.00 & + 0.50 & + 0.38 \\ - 0.13 & 0.00 & 0.00 & + 0.50 & + 0.63\end{matrix} ]$$

$${BHC}_{T 4} = [ \begin{matrix}+ 0.83 & + 0.50 & - 0.33 & 0.00 & 0.00 \\ + 0.33 & + 0.50 & + 0.17 & 0.00 & 0.00 \\ - 0.06 & + 0.50 & + 0.45 & 0.00 & + 0.11 \\ - 0.17 & + 0.50 & + 0.17 & 0.00 & + 0.50 \\ - 0.17 & + 0.50 & - 0.33 & 0.00 & + 1.00\end{matrix} ]$$

$${BHC}_{T 5} = [ \begin{matrix}+ 0.75 & + 0.60 & - 0.25 & - 0.10 & 0.00 \\ + 0.25 & + 0.60 & + 0.25 & - 0.10 & 0.00 \\ 0.00 & + 0.30 & + 0.50 & + 0.20 & 0.00 \\ - 0.13 & 0.00 & + 0.63 & + 0.50 & 0.00 \\ - 0.38 & 0.00 & + 0.88 & + 0.50 & 0.00\end{matrix} ]$$

Thus, as shown above, if antenna transmitter T1 is determined to be unhealthy, the borehole compensation matrix BHC_{T1} eliminates the contribution of antenna transmitter T1 to the combined attenuation measurements, i.e., the first column in borehole compensation matrix BHC_{T1} is zero for all focuses. Similarly, if antenna transmitter T2 is determined to be unhealthy, the borehole compensation matrix BHC_{T2} eliminates the contribution of antenna transmitter T2 to the combined attenuation measurements, i.e., the second column in borehole compensation matrix BHC_{T2} is zero for all focuses. In this manner, the borehole compensation matrices depicted above may compensate for an identified unhealthy antenna. However, it should be appreciated that the above borehole compensation matrices are merely examples that may be used in some embodiments of an electromagnetic measurement tool. In other embodiments, different borehole compensation matrices may be used, such as for tools having a different numbers and/or combinations of antenna transmitters and antenna receivers.

As shown in FIG. 10, after selection of a borehole compensation matrix, the tool may continue to be operated using the selected borehole compensation matrix (block 1016). For example, formation resistivity may be determined using the selected borehole compensation matric (1018). As noted above in such embodiments, the process 1000 may enable continued downhole operation of an electromagnetic measurement tool having an unhealthy antenna transmitter without removing the tool from downhole. Thus, the combining of the attenuation measurements may compensate for the unhealthy antenna transmitter by using the appropriate borehole compensation matrix, thus eliminating the need to pull the electromagnetic measurement tool and repair or replace the unhealthy antenna transmitter.

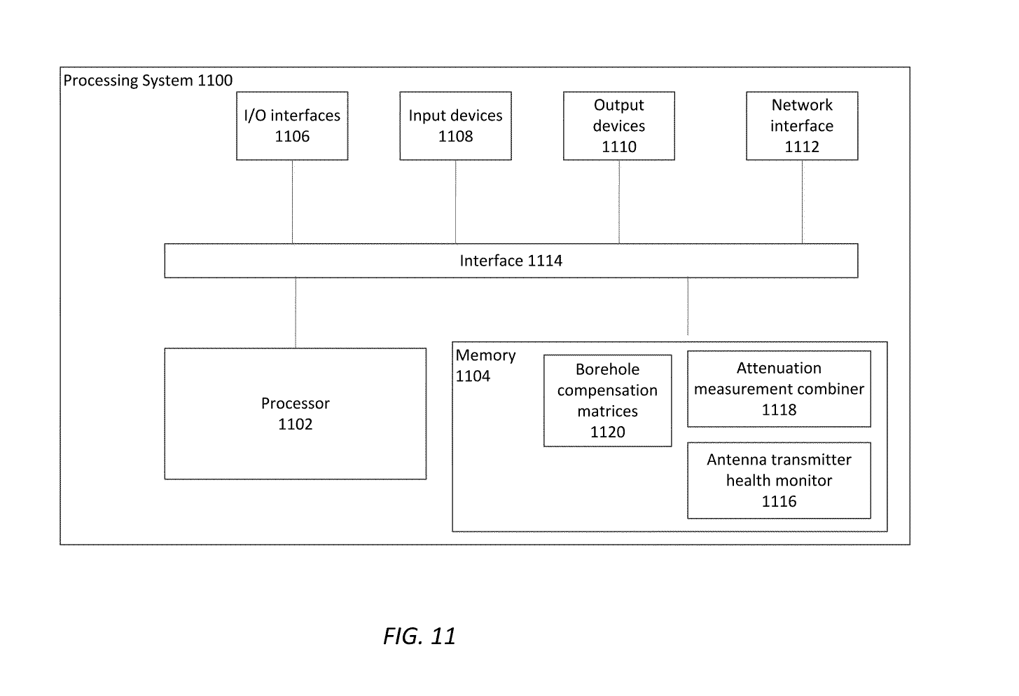

FIG. 11 is a block diagram of further details of an example control system 1100 (e.g., control system 152) that may execute example machine-readable instructions used to implement one or more of processes described herein and, in some embodiments, to implement a portion of one or more of the example downhole tools described herein. The control system 1100 may be or include, for example, controllers (e.g., processor 1102), special-purpose computing devices, servers, personal computers, personal digital assistant (PDA) devices, tablet computers, wearable computing devices, smartphones, internet appliances, and/or other types of computing devices. Moreover, it is also contemplated that one or more components or functions of the system 1100 may be implemented in wellsite surface equipment. As shown in the embodiment illustrated in FIG. 11, the processing system 1100 may include one or more processors (e.g., processor 1102), a memory 1104, I/O ports 1106 input devices 1108, output devices 1110, and a network interface 1112. The control system 1100 may also include one or more additional interfaces 1114 to facilitate communication between the various components of the system 1100.

The processor 1102 may provide the processing capability to execute programs, user interfaces, and other functions of the system 1100. The processor 1102 may include one or more processors and may include “general-purpose” microprocessors, special purpose microprocessors, such as application-specific integrated circuits (ASICs), or any combination thereof. In some embodiments, the processor 1102 may include one or more reduced instruction set (RISC) processors, such as those implementing the Advanced RISC Machine (ARM) instruction set. Additionally, the processor 1102 may include single-core processors and multicore processors and may include graphics processors, video processors, and related chip sets. Accordingly, the system 1100 may be a uni-processor system having one processor (e.g., processor 1102), or a multi-processor system having two or more suitable processors (e.g., 1102). Multiple processors may be employed to provide for parallel or sequential execution of the techniques described herein. Processes, such as logic flows, described herein may be performed by the processor 1102 executing one or more computer programs to perform functions by operating on input data and generating corresponding output. The processor 1102 may receive instructions and data from a memory (e.g., memory 1104).

The memory 1104 (which may include one or more tangible non-transitory computer readable storage mediums) may include volatile memory and non-volatile memory accessible by the processor 1102 and other components of the system 1100. For example, the memory 1104 may include volatile memory, such as random access memory (RAM). The memory 1104 may also include non-volatile memory, such as ROM, flash memory, a hard drive, other suitable optical, magnetic, or solid-state storage mediums or any combination thereof. The memory 1104 may store a variety of information and may be used for a variety of purposes. For example, the memory 1104 may store program instructions in the form of executable computer code, such as the firmware for the system 1100, an operating system for the system 1100, and any other programs or other executable code for providing functions of the system 1100. Program instructions may include computer program instructions for implementing one or more techniques described herein. Program instructions may include a computer program (which in certain forms is known as a program, software, software application, script, or code). Such executable computer code may include, for example, an antenna transmitter health monitor 1116 and an attenuation measurement combiner 1118 executable by the one or more processors 1102. Additionally, the memory 1104 may store borehole compensation matrices 1120 for use by the control system 1100. For example, the antenna transmitter health monitor 1116 may implement one or more of the techniques described above for determining the health of antenna transmitters of an electromagnetic measurement tool coupled to the control system 1100. In some embodiments, as noted above, antenna transmitter health monitor 1116 may provide information, such as notifications, to output devices (e.g., a display) of the control system 1100. In another example, the attenuation measurement combiner 1118 may implement the techniques described above for using a replacement borehole compensation matrix based on an identified unhealthy antenna transmitter. In some embodiments, for example, the attenuation measurement combiner 1118 may access the stored borehole compensation matrices 1120. The stored borehole compensation matrices 1120 may include one or more borehole compensation matrices for use with an identified unhealthy antenna transmitter. In some embodiments, the stored borehole compensation matrices 1120 may include a replacement borehole compensation matrices for each antenna transmitter of an electromagnetic measurement tool coupled to the control system 1100.

The interface 1114 may include multiple interfaces and may enable communication between various components of the system 1100, the processor 1102, and the memory 1104. In some embodiments, the interface 1114, the processor 1102, memory 1104, and one or more other components of the system 1100 may be implemented on a single chip, such as a system-on-a-chip (SOC). In other embodiments, these components, their functionalities, or both may be implemented on separate chips. The interface 1114 may enable communication between processors (e.g., processor 1102), the memory 1104, the network interface 1112, or any other devices of the system 1100 or a combination thereof. The interface 1114 may implement any suitable types of interfaces, such as Peripheral Component Interconnect (PCI) interfaces, the Universal Serial Bus (USB) interfaces, Thunderbolt interfaces, Firewire (IEEE-1394) interfaces, and so on.

The system 1100 may also include an input and output port 1106 to enable connection of additional devices, such as I/O devices 1108, 1110. Embodiments of the present disclosure may include any number of input and output ports 1106, including headphone and headset jacks, universal serial bus (USB) ports, Firewire (IEEE-1394) ports, Thunderbolt ports, and AC and DC power connectors. Further, the system 1100 may use the input and output ports to connect to and send or receive data with any other device, such as other portable computers, personal computers, printers, etc.

The control system 1100 may include one or more input devices 1108. The input device(s) 1108 permit a user to enter data and commands used and executed by the processor 1102. The input device 1108 may include, for example, a keyboard, a mouse, a touchscreen, a track-pad, a trackball, an isopoint, and/or a voice recognition system, among others. The processing system 1100 may also include one or more output devices 1110. The output devices 1110 may include, for example, display devices (e.g., a liquid crystal display or cathode ray tube display (CRT), among others), printers, and/or speakers, among others.

The system 1100 depicted in FIG. 11 also includes a network interface 1112. The network interface 1112 may include a wired network interface card (NIC), a wireless (e.g., radio frequency) network interface card, or combination thereof. The network interface 1112 may include known circuitry for receiving and sending signals to and from communications networks, such as an antenna system, an RF transceiver, an amplifier, a tuner, an oscillator, a digital signal processor, a modem, a subscriber identity module (SIM) card, memory, and so forth. The network interface 1112 may communicate with networks, such as the Internet, an intranet, a cellular telephone network, a wide area network (WAN), a local area network (LAN), a metropolitan area network (MAN), or other devices by wired or wireless communication using any suitable communications standard, protocol, or technology.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language is not generally intended to imply that features, elements, and/or operations are in any way used for one or more implementations or that one or more implementations necessarily include logic for deciding, with or without user input or prompting, whether these features, elements, and/or operations are included or are to be performed in any particular implementation.

Many modifications and other implementations of the disclosure set forth herein will be apparent having the benefit of the teachings presented in the foregoing descriptions and the associated drawings. Therefore, it is to be understood that the disclosure is not to be limited to the specific implementations disclosed and that modifications and other implementations are intended to be included within the scope of the appended claims. Although specific terms are employed herein, they are used in a generic and descriptive sense and not for purposes of limitation.

What is claimed is:

1. A method, comprising:
receiving a voltage proportional to an input current provided to an antenna transmitter of an electromagnetic measurement tool disposed in a wellbore, the electromagnetic measurement tool comprising the antenna transmitter and at least one antenna receiver;
comparing the voltage to a threshold voltage; and
identifying the antenna transmitter as unsuitable for operation if the voltage is below the threshold voltage.

2. The method of claim 1, further comprising identifying the antenna transmitter as suitable for operation if the voltage is above the threshold voltage.

3. The method of claim 1, wherein the electromagnetic measurement tool comprises an input current measurement circuit, wherein the input current measurement circuit comprises a sense resistor coupled to a high voltage driver block of the electromagnetic measurement tool.

4. The method of claim 3, wherein the received voltage corresponds to a voltage produced by a driver block coupled to the sense resistor.

5. The method of claim 1, wherein the electromagnetic measurement tool comprises five antenna transmitters.

6. The method of claim 1, further comprising providing a notification in a control system coupled to the electromagnetic measurement tool if the voltage is below the threshold voltage.

7. The method of claim 1, further comprising:
selecting, based on the identity of the antenna transmitter, a replacement borehole compensation matrix from a plurality of borehole compensation matrices; and
determining a combined attenuation measurement from the electromagnetic measurement tool using the replacement borehole compensation matrix.

8. A method, comprising:
monitoring at least one antenna transmitter of an electromagnetic measurement tool disposed in a wellbore, the electromagnetic measurement tool comprising a plurality of antenna transmitters and at least one antenna receiver;
determining a combined attenuation measurement using a first borehole compensation matrix;
identifying one of the plurality of antenna transmitters as unsuitable for operation;
selecting, based on the identified antenna transmitter, a replacement borehole compensation matrix from a plurality of borehole compensation matrices; and
determining a combined attenuation measurement using the replacement compensation matrix associated with the plurality of antenna transmitters.

9. The method of claim 8, wherein monitoring at least one antenna transmitter of an electromagnetic measurement tool disposed in a wellbore comprises:
receiving a voltage proportional to an input current provided to the at least one antenna transmitter; and
comparing the voltage to a threshold voltage.

10. The method of claim 8, wherein the selected replacement borehole compensation matrix eliminates attenuation measurement contributions from the identified antenna transmitter.

11. The method of claim 8, wherein each of the plurality of borehole compensation matrices comprises a respective borehole compensation matrix for each of the plurality of antenna transmitters.

12. The method of claim 8, wherein the borehole compensation matrices each comprises a row corresponding to a focus of an attenuation measurement and a column corresponding to one of the plurality of antenna transmitters.

13. The method of claim 1, wherein monitoring at least one antenna transmitter of an electromagnetic measurement tool disposed in a wellbore comprises continuously monitoring the at least one an antenna transmitter in real-time.

14. A system, comprising:
a processor;
at least one memory storing computer-executable instructions, that when executed, causes the at least one processor to:
monitor at least one antenna transmitter of an electromagnetic measurement tool disposed in a wellbore, the electromagnetic measurement tool comprising a plurality of antenna transmitters and at least one antenna receiver;
determine a combined attenuation measurement using a first borehole compensation matrix associated with the plurality of antenna transmitters;
identify one of the plurality of antenna transmitters as unsuitable for operation;
select, based on the identified antenna transmitter, a replacement borehole compensation matrix from a plurality of borehole compensation matrices; and
determine a combined attenuation measurement using the replacement compensation matrix associated with the plurality of antenna transmitters.

15. A method, comprising:
receiving a first signal from at least one receiver associated with an electromagnetic measurement tool; the received signal responsive to operation of an antenna transmitter of the electromagnetic measurement tool;
comparing a property of the received signal to a threshold, wherein the property comprises one of a peak voltage, a linearity of the received signal, or an average phase of the first signal and a second signal received at the at least one receiver; and
identifying the antenna transmitter as unsuitable for operation if the property is below the threshold voltage.

16. The method of claim 15, further comprising identifying the antenna transmitter as suitable for operation if the property is above the threshold voltage.

17. The method of claim 15, further comprising operating the antenna transmitter over a frequency range.

18. The method of claim 15, further comprising operating the antenna transmitter over an amplitude range.

19. The method of claim 15, wherein the at least on receiver comprises an antenna receiver of the electromagnetic measurement tool.

20. The method of claim 15, further comprising receiving a second signal from a second receiver of the at least one receiver associated with the electromagnetic measurement tool.
